(19) United States
(12) Patent Application Publication
(10) Pub. No.: US 2026/0123073 A1
(43) Pub. Date: Apr. 30, 2026

(54) IMAGE SENSOR

(71) Applicant: Samsung Electronics Co., Ltd., Suwon-si (KR)

(72) Inventors: Sungjun IN, Suwon-si (KR); Seonghoon KO, Suwon-si (KR); Sungchul KIM, Suwon-si (KR); Jae Ho KIM, Suwon-si (KR); Yonghee PARK, Suwon-si (KR)

(73) Assignee: Samsung Electronics Co., Ltd., Suwon-si (KR)

(21) Appl. No.: 19/181,865

(22) Filed: Apr. 17, 2025

(30) Foreign Application Priority Data
Oct. 24, 2024 (KR) 10-2024-0146255

(51) Int. Cl. H10F 39/00

(52) U.S. Cl. CPC H10F 39/8053; H10F 39/8057; H10F 39/807

(57) ABSTRACT

An image sensor may include a substrate including a plurality of photoelectric conversion parts, and a first optical filter and a second optical filter on a top surface of the substrate and spaced apart from each other in a first direction. The first optical filter comprises a stack structure and an optical absorption layer covering the stack structure, the stack structure extending in the first direction, the stack structure comprises a metal pattern and a dielectric pattern on the metal pattern, and the second optical filter comprises at least one of a red color filter, a green color filter, and a blue color filter.

### CROSS-REFERENCE TO RELATED APPLICATIONS

This U.S. non-provisional patent application claims priority under 35 U.S. C. § 119 to Korean Patent Application No. 10-2024-0146255, filed on Oct. 24, 2024, in the Korean Intellectual Property Office, the entire contents of which are hereby incorporated by reference.

### BACKGROUND

Example embodiments of the present disclosure relate to an image sensor, and in particular, to an image sensor with improved electrical and/or optical properties.

An image sensor is a semiconductor device capable of converting an optical image to electric signals. The image sensor may be classified into two types: a charge coupled device (CCD) type, and a complementary metal-oxide-semiconductor (CMOS) type. The CMOS-type image sensor is called CIS for short. The CIS may include a plurality of pixels that are two-dimensionally arranged. Each of the pixels may include a photodiode (PD). Each of the pixels includes a photodiode (PD), which is used to convert incident light to an electric signal.

### SUMMARY

Some example embodiments of the inventive concepts provide an image sensor including an optical filter with higher infrared transmittance and having reduced noise and/or improved sensitivity.

According to some example embodiments of the inventive concepts, an image sensor may include a substrate including a plurality of photoelectric conversion parts, and a first optical filter and a second optical filter on a top surface of the substrate and spaced apart from each other in a first direction. The first optical filter comprises a stack structure and an optical absorption layer covering the stack structure, the stack structure extending in the first direction, the stack structure comprises a metal pattern and a dielectric pattern on the metal pattern, and the second optical filter comprises at least one of a red color filter, a green color filter, and a blue color filter.

According to some example embodiments of the inventive concepts, an image sensor may include a substrate including a plurality of photoelectric conversion parts, and a first optical filter and a second optical filter on a top surface of the substrate and spaced apart from each other in a first direction, the first direction being parallel to the top surface of the substrate. The first optical filter comprises a plurality of first stack structures spaced apart from each other in the first direction and arranged along a row, and an optical absorption layer covering the first stack structures, each of the first stack structures extends in a second direction, is the second direction being parallel to the top surface of the substrate and perpendicular to the first direction, each of the first stack structures includes a first material pattern and a second material pattern alternately stacked, the first material pattern and the second material pattern comprise different materials from each other, and the second optical filter is at least one of a red color filter, a green color filter, and a blue color filter.

According to some example embodiments of the inventive concepts, an image sensor may include a substrate comprising a sensing region, an optical black region, and a pad region, and the substrate having a first surface and a second surface opposite to each other, a plurality of photoelectric conversion parts in the sensing region of the substrate, an isolation structure in the substrate separating the photoelectric conversion parts from each other, and a first optical filter and a second optical filter on the first surface of the substrate. The first and second optical filters are spaced apart from each other in a first direction, the first direction being parallel to the first surface, the first optical filter comprises a plurality of stack structures and a first color filter, the second optical filter comprises a second color filter, each of the stack structures comprises a plurality of metal patterns and a plurality of dielectric patterns, the plurality of metal patterns and the plurality of dielectric patterns in the first optical filter are alternately stacked in a vertical direction, the first color filter in the first optical filter fills a region between the stack structures and covers the stack structures, the first color filter comprises a blue color filter, and the second color filter comprises at least one of a blue color filter, a green color filter, and a red color filter.

According to some example embodiments of the inventive concepts, a method of manufacturing an optical filter of an image sensor may include forming a sacrificial layer on a substrate, forming mask patterns on the sacrificial layer, patterning the sacrificial layer using the mask patterns as an etch mask, removing the mask pattern, forming first stack structures between the sacrificial patterns, removing the sacrificial patterns, forming an optical absorption layer on the top and sides of the first stack structure. The forming of the first stack structures is comprises forming a plurality of dielectric patterns and a plurality of metal patterns alternately stacked.

According to some example embodiments of the inventive concepts, a method of manufacturing an optical filter of an image sensor may include forming a first stack layer on a substrate, forming a mask pattern on the first stack layer, patterning the first stack layer using the mask patterns as an etch mask to make a first stack structure, removing the mask pattern, forming an optical absorption layer on the top and sides of the first stack structure. The forming of the first stack layer is comprises forming a plurality of dielectric layers and a plurality of metal layers alternately stacked.

### BRIEF DESCRIPTION OF THE DRAWINGS

FIG. 1 is a plan view illustrating an image sensor according to some example embodiments of the inventive concepts.

FIG. 2 is a sectional view taken along a line A-A′ of FIG. 1.

FIG. 3A is a diagram illustrating an array of first and second optical filters according to some example embodiments of the inventive concepts.

FIG. 3B is a diagram illustrating an array of first and second optical filters according to some example embodiments of the inventive concepts.

FIG. 4 is a plan view illustrating a first optical filter according to some example embodiments of the inventive concepts.

FIG. 5 is a sectional view taken along a line B-B′ of FIG. 4.

FIG. 6 is a sectional view taken along a line C-C′ of FIG. 4.

FIG. 7 is a plan view illustrating a first optical filter according to some example embodiments of the inventive concepts.

FIG. 8 is a sectional view taken along a line D-D′ of FIG. 7.

FIG. 9 is a sectional view taken along a line E-E′ of FIG. 7.

FIGS. 10, 11, and 12 are sectional views illustrating a process of fabricating a first optical filter, according to some example embodiments of the inventive concepts.

FIGS. 13 and 14 are sectional views illustrating a process of fabricating a first optical filter, according to some example embodiments of the inventive concepts.

FIG. 15 is a sectional view illustrating an image sensor according to some example embodiments of the inventive concepts.

FIG. 16 is a sectional view illustrating an image sensor according to some example embodiments of the inventive concepts.

### DETAILED DESCRIPTION

Some example embodiments of the inventive concepts will now be described more fully with reference to the accompanying drawings, in which example embodiments are shown.

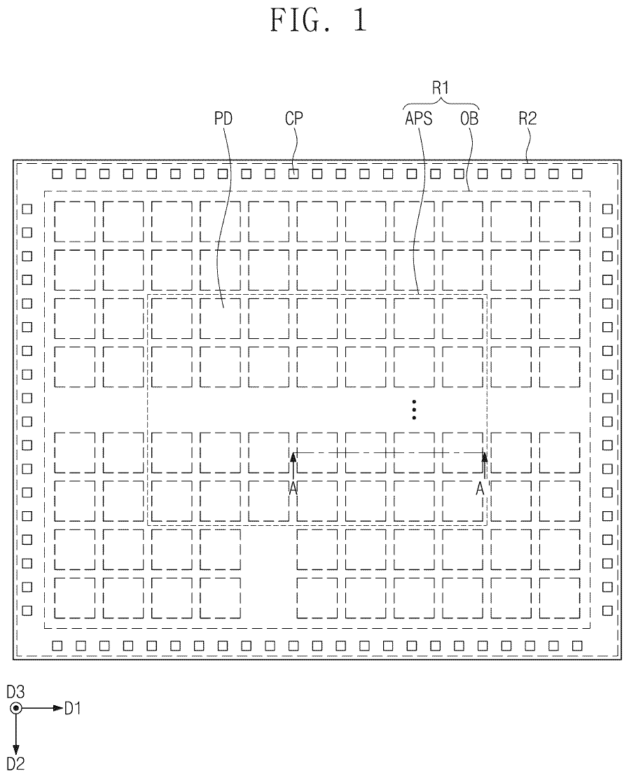

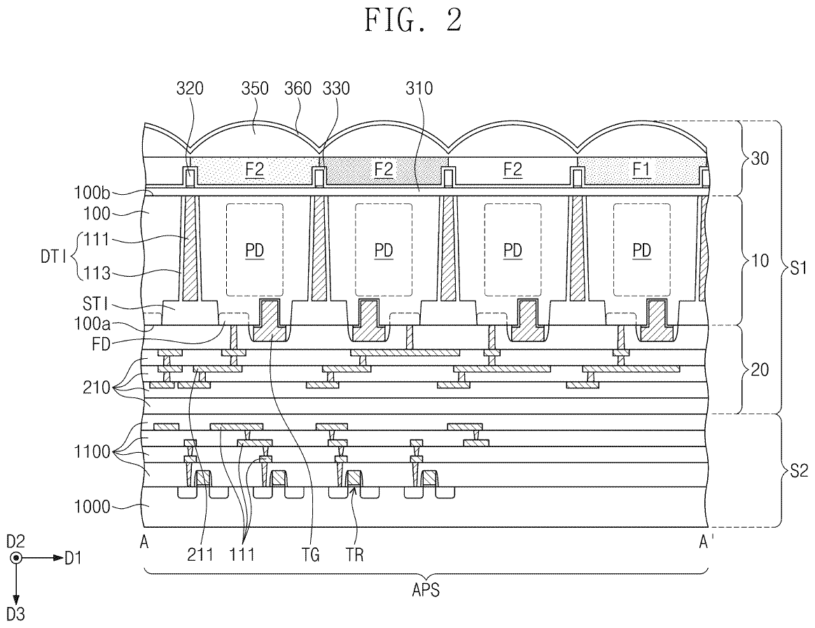

FIG. 1 is a plan view illustrating an image sensor according to some example embodiments of the inventive concepts. FIG. 2 is a sectional view taken along a line A-A′ of FIG. 1.

Referring to FIGS. 1 and 2, an image sensor may include a first chip S1 and a second chip S2. In the present specification, individual chips may be defined as stacking structures, which are formed from different semiconductor wafers. Depending on the bonding shape of the chips and the bonding material between the chips, a boundary between the individual chips may not be clearly observed, but in such a stacking structure, the individual chips should be understood as being formed from different semiconductor wafers.

The first chip S1 may be a sensor chip. The second chip S2 may be a logic chip. The first chip S1 may be configured to have an image sensing function. In some example embodiments, the second chip S2 may include circuits, which are configured to drive the first chip S1 and may be used to store electrical signals produced in the first chip S1.

The first chip S1 may include a substrate 100. The substrate 100 may include a first surface 100a and a second surface 100b, which are opposite to each other. Light may be incident into the substrate 100 through the second surface 100b. In the present specification, the first surface 100a may correspond to a bottom surface of the substrate 100. The second surface 100b may correspond to a top surface of the substrate 100. The substrate 100 may be a single crystalline wafer or an epitaxial layer, which is formed of silicon and/or germanium, or a silicon-on-insulator (SOI) substrate. However, example embodiments are not limited thereto.

In the present specification, a first direction D1 may be parallel to the first surface 100a of the substrate 100. A second direction D2 may be parallel to the first surface 100a of the substrate 100 and may be perpendicular to the first direction D1. A third direction D3 may be perpendicular to the first surface 100a of the substrate 100.

The first chip S1 may include an array region R1 and a pad region R2. The array region R1 may include a plurality of photoelectric conversion parts PD, which are two-dimensionally arranged in the first and second directions D1 and D2.

The array region R1 may include a sensing region APS and an optical black region OB. When viewed in a plan view, the optical black region OB may be provided to enclose the sensing region APS. The optical black region OB may include portions, to which light is not incident.

A plurality of conductive pads CP, which are used to input or output control signals and photoelectric signal, may be disposed in the pad region R2. When viewed in a plan view, the pad region R2 may be provided to enclose the array region R1.

Referring back to FIG. 2, the image sensor may include a photoelectric conversion layer 10, an interconnection layer 20, and an optically-transparent layer 30, when viewed in a vertical sectional view. The photoelectric conversion layer 10 may be disposed between the interconnection layer 20 and the optically-transparent layer 30. The photoelectric conversion layer 10 may be configured to convert light, which is incident from the outside, to electrical signals. The photoelectric conversion layer 10 may include not only the substrate 100 but also isolation structures DTI and the photoelectric conversion parts PD, which are disposed in the substrate 100.

The substrate 100 may be doped with a first impurity to have a first conductivity type. For example, the first impurity may be boron, but example embodiments are not limited thereto. The first conductivity type may be, for example, a p-type.

The photoelectric conversion parts PD may be disposed in the substrate 100. The photoelectric conversion part PD may be doped with a second impurity to have a second conductivity type different from the first conductivity type. The second impurity may be, for example, phosphorus or arsenic. However, example embodiments are not limited thereto. The second conductivity type may be, for example, an n-type. Here, an n-type region of the photoelectric conversion part PD and the p-type region of the substrate 100 may form a p-n junction serving as a photodiode, and if light is incident to the p-n junction, electron-hole pairs may be generated from the p-n junction. Electrons, which are generated through this process, may be transferred to the photoelectric conversion part PD.

A device isolation portion STI may be disposed on the first surface 100a of the substrate 100. The device isolation portion STI may include at least one of silicon oxide, silicon nitride, or silicon oxynitride. However, example embodiments are not limited thereto.

An isolation structure DTI may be disposed in the substrate 100 to separate the photoelectric conversion parts PD from each other. The isolation structure DTI may be contact with the device isolation portion STI. The isolation structure DTI may have a width that decreases as a distance from the first surface 100a increases in a direction toward the second surface 100b.

The isolation structure DTI may include a first isolation pattern 111 and a second isolation pattern 113. The first isolation pattern 111 may be disposed to be spaced apart from the substrate 100. The first isolation pattern 111 may include a material having a refractive index different from the substrate 100. The first isolation pattern 111 may be formed of or include at least one of doped polysilicon, metallic materials, or insulating materials. However, example embodiments are not limited thereto.

The second isolation pattern 113 may be interposed between the first isolation pattern 111 and the substrate 100. The second isolation pattern 113 may include an insulating material having a refractive index different from the substrate 100. In some example embodiments, the second isolation pattern 113 may be formed of or include silicon oxide. However, example embodiments are not limited thereto.

An example embodiment, a negative bias voltage may be applied to the first isolation pattern 111. The first isolation pattern 111 may serve as a common bias line. In this case, the dark current property of the image sensor may be improved because the negative bias voltage immobilizes holes, which may exist on a surface of the substrate 100 in contact with the isolation structure DTI.

Although the device isolation portion STI and the isolation structure DTI are illustrated to have a boundary therebetween, there may be no observable boundary between the device isolation portion STI and the isolation structure DTI. In some example embodiments, there may be no interface between the device isolation portion STI and the second isolation pattern 113.

A transfer transistor TG may be disposed on the first surface 100a of the substrate 100. In some example embodiments, a portion of the transfer transistor TG may be extended into the substrate 100. A remaining portion of the transfer transistor TG may be provided on the first surface 100a. A gate insulating layer may be interposed between the transfer transistor TG and the substrate 100.

A floating diffusion region FD may be disposed in the substrate 100 and adjacent to the transfer transistor TG. The floating diffusion region FD may be doped with a second impurity to have a second conductivity type.

Although not shown, a reset transistor, a source follower transistor, and a selection transistor, and the transfer transistor TG, may be provided on the first surface 100a of the substrate 100. The photoelectric conversion part PD together with the transfer transistor TG, the reset transistor, the source follower transistor, and the selection transistor may constitute a unit pixel.

The interconnection layer 20 may be disposed on the first surface 100a of the substrate 100. The interconnection layer 20 may include a plurality of interlayer insulating layers 210 and a plurality of interconnection patterns 211.

The optically-transparent layer 30 may be disposed on the second surface 100b of the substrate 100. The optically-transparent layer 30 may include a fixed charge layer 310, a grid 320, a protection layer 330, a first optical filter F1, a second optical filter F2, micro lenses 350, and a passivation layer 360. The optically-transparent layer 30 may be configured to perform an operation of focusing and filtering light, which is incident from the outside, and to provide the light to the photoelectric conversion layer 10.

The fixed charge layer 310 may be in contact with the second surface 100b of the substrate 100. The fixed charge layer 310 may be formed of a metal oxide layer, whose oxygen content is lower than its stoichiometric ratio, or a metal fluoride layer, whose fluorine content ratio is lower than its stoichiometric ratio. Thus, the fixed charge layer 310 may have negative fixed charges. The fixed charge layer 310 may be formed of metal oxide or metal fluoride containing at least one metal, which is selected from the group consisting of hafnium (Hf), zirconium (Zr), aluminum (Al), tantalum (Ta), titanium (Ti), yttrium (Y), and lanthanoid. However, example embodiments are not limited thereto. The hole accumulation may occur near the fixed charge layer 310. In this case, it may be possible to effectively suppress the dark current issue and the white spot issue. In some example embodiments, the fixed charge layer 310 may be formed of or include at least one of aluminum oxide or hafnium oxide. However, example embodiments are not limited thereto.

The grids 320 may be disposed on the fixed charge layer 310. Each of the grids 320 may include a light-blocking pattern and/or a low refractive pattern. The light-blocking pattern may be formed of or include at least one of metallic materials (e.g., titanium, tantalum, or tungsten). The low-refractive pattern may be formed of or include a material whose refractive index is lower than the light-blocking pattern. The low refractive pattern may be formed of an organic material and may have a refractive index of about 1.1 to 1.3.

The protection layer 330 may cover the fixed charge layer 310 and the grid 320. The protection layer 330 may be formed of or include at least one of aluminum oxide or silicon oxide. However, example embodiments are not limited thereto.

The first and second optical filters F1 and F2 may be disposed on the second surface 100b and between the grids 320. The first and second optical filters F1 and F2 may be spaced apart from each other in the first direction D1. A height of the first optical filter F1 may be substantially equal to or substantially equal to a height of the second optical filter F2. In some example embodiments, the height of the first optical filter F1 in a third direction and the height of the second optical filter F2 in the third direction may range from 400 nm to 800 nm.

The first optical filter structure F1 may include a first color filter. The second optical filter structure F2 may include a second color filter. The first color filter may be a blue color filter. The second color filter may be one of blue, green, and red color filters. The first optical filter structure F1 will be described in more detail below.

The micro lenses 350 may be disposed on the first and second optical filters F1 and F2. The micro lenses 350 may have a convex shape and may have a specific curvature radius. The micro lenses 350 may include an optically transparent resin.

The passivation layer 360 may be placed on the micro lenses 350 to conformally cover the surface of the micro lenses 350. The passivation layer 360 may include, for example, an inorganic oxide material.

The second chip S2 may be provided below the first chip S1. The second chip S2 may include a logic substrate 1000, logic circuits TR, interconnection structures 1111 connected to the logic circuits TR, and logic interlayer insulating layers 1100. The uppermost one of the logic interlayer insulating layers 1100 may be bonded to the interconnection layer 20 of the first chip S1. Although not shown, the second chip S2 may be electrically connected to the first chip S1 through penetration electrodes or bonding pads.

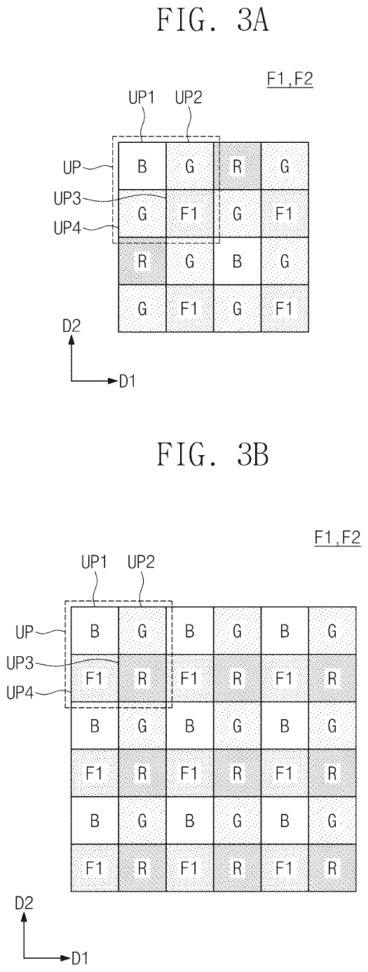

FIG. 3A is a diagram illustrating an array of first and second optical filters according to some example embodiments of the inventive concepts.

Referring to FIGS. 2 and 3A, the first and second optical filters F1 and F2 may have an array structure, in which unit patterns UP are two-dimensionally arranged. In some example embodiments, the unit patterns UP may have a 2×2 matrix structure.

The unit pattern UP may be composed of first to fourth unit filters UP1 to UP4. The first unit filter UP1, the second unit filter UP2, and the fourth unit filter UP4 may be the second optical filter F2 described with reference to FIG. 2. The third unit filter UP3 may be the first optical filter F1 described with reference to FIG. 2.

The first to fourth unit filters UP1 to UP4 may be disposed in a clockwise direction. In some example embodiments, the first and second unit filters UP1 and UP2 may be adjacent to each other in the first direction D1. The second and third unit filters UP2 and UP3 may be adjacent to each other in the second direction D2. The third and fourth unit filters UP3 and UP4 may be adjacent to each other in the first direction D1. The first and fourth unit filters UP1 and UP4 may be adjacent to each other in the second direction D2.

The first unit filter UP1 may be, for example, a blue color filter B. The second unit filter UP2 may be, for example, a green color filter G. The third unit filter UP3 may be, for example, an infrared light filter F1. The fourth unit filter UP4 may be, for example, the green color filter G. Here, the first unit filter UP1 of another unit pattern UP, which is adjacent thereto in the first and/or second directions D1 and/or D2, may be a red color filter R. The infrared light filter F1 may be surrounded by the second optical filters F2 in a plan view perspective.

FIG. 3B is a diagram illustrating an array of first and second optical filters according to some example embodiments of the inventive concepts. For concise description, an element previously described with reference to FIG. 3A may be identified by the same reference number without repeating an overlapping description thereof.

Referring to FIGS. 2 and 3B, the first and second optical filters F1 and F2 may have an array structure, in which unit patterns UP are two-dimensionally arranged. In some example embodiments, the unit pattern UP may have a 3×3 matrix structure.

The unit pattern UP may be composed of the first to fourth unit filters UP1 to UP4. The first unit filter UP1, the second unit filter UP2, and the third unit filter UP3 may be the second optical filter F2 described with reference to FIG. 2. The fourth unit filter UP4 may be the first optical filter F1 described with reference to FIG. 2.

The first unit filter UP1 may be the blue color filter B. The second unit filter UP2 may be, for example, the green color filter G. The third unit filter UP3 may be, for example, the red color filter R. The fourth unit filter UP4 may be, for example, the infrared light filter F1. The infrared light filter F1 may be surrounded by the second optical filters F2 in a plan view perspective.

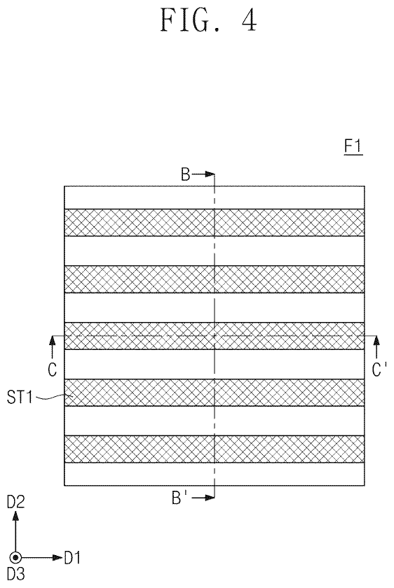

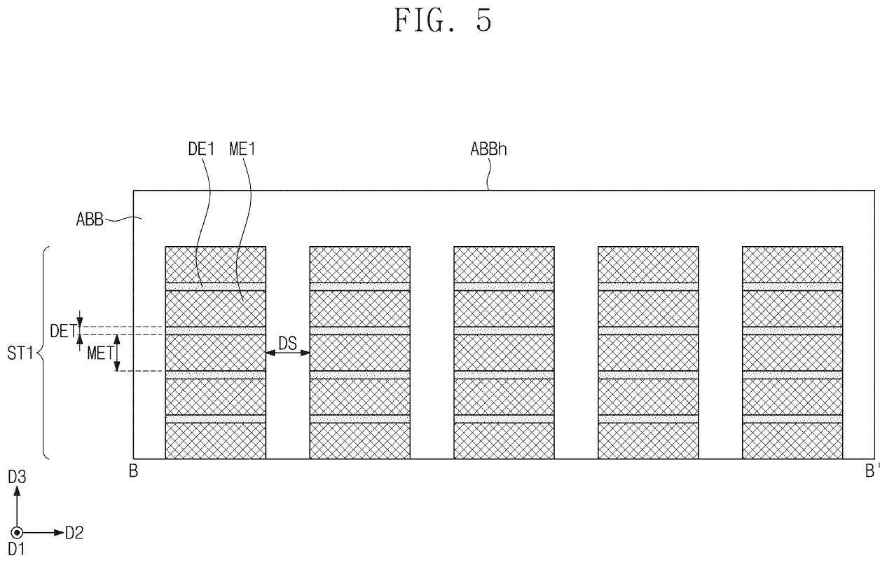

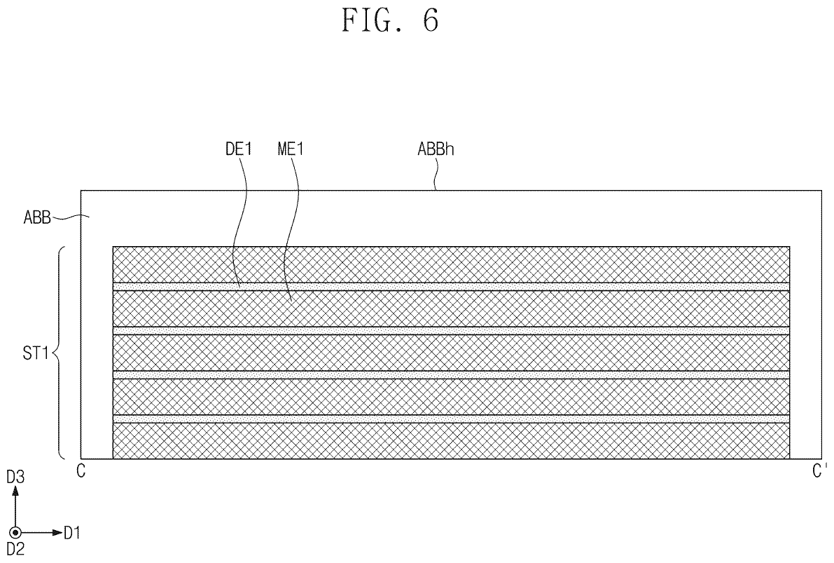

FIG. 4 is a plan view illustrating a first optical filter according to some example embodiments of the inventive concepts. FIG. 5 is a sectional view taken along a line B-B′ of FIG. 4. FIG. 6 is a sectional view taken along a line C-C′ of FIG. 4.

Referring to FIGS. 2, 4, 5, and 6, the first optical filter F1 may include a plurality of first stack structures ST1 and an optical absorption layer ABB. In the present specification, the optical absorption layer ABB may be referred to as a first color filter ABB.

The first stack structures ST1 may be extended in the first direction D1. In the first optical filter F1, each of the first stack structures ST1 may be disposed along a row. The first stack structures ST1 may be spaced apart from each other in the second direction D2. In some example embodiments, a distance DS between the first stack structures ST1 in the second direction D2 may range from 700 nm to 800 nm.

Each of the first stack structures ST1 may include first metal patterns ME1 and first dielectric patterns DE1. In the present specification, the metal pattern may be referred to as a first material pattern. The dielectric pattern may be referred to as a second material pattern.

The first dielectric pattern DE1 may be disposed on the first metal pattern ME1. In some example embodiments, a plurality of first metal patterns ME1 and a plurality of first dielectric patterns DE1 may be alternately stacked in the third direction D3. Here, the first metal pattern ME1 may be disposed as the uppermost pattern of the first stack structure ST1.

A thickness MET of the first metal pattern ME1 may be larger than a thickness DET of the first dielectric pattern DE1. In some example embodiments, the thickness MET of the first metal pattern ME1 may be 5 to 10 times the thickness DET of the first dielectric pattern DE1.

The first metal pattern ME1 and the first dielectric pattern DE1 may include different materials from each other. The first metal pattern ME1 may be formed of or include at least one of, for example, gold, silver, or copper. The first dielectric pattern DE1 may be formed of or include at least one of silicon oxide or silicon nitride. However, example embodiments are not limited thereto.

Here, in the case where incident light passes through the first optical filter F1, light, which has a wavelength different from that of infrared light, may be absorbed or reflected, due to the plasmonic effect caused by the first metal pattern ME1 and the first dielectric pattern DE1 in the first stack structure ST1.

The optical absorption layer ABB may be provided in the first optical filter F1 to fill a space between the first stack structures ST1 and to cover the first stack structures ST1. The optical absorption layer ABB may include, for example, a blue pigment. The optical absorption layer ABB may be formed of or include at least one of copper phthalocyanine (CuPc) or cobalt aluminum oxide (CoAl₂O₄). However, example embodiments are not limited thereto.

A height of the first stack structures ST1 may be lower than a level of a top surface ABBh of the optical absorption layer ABB. In the present specification, a level of the top surface ABBh of the optical absorption layer ABB may correspond to the height of the first optical filter F1. In some example embodiments, the height of the first stack structures ST1 may be 60% to 80% of the height of the first optical filter F1.

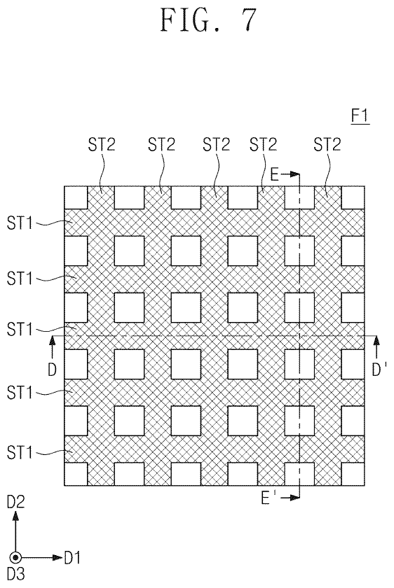

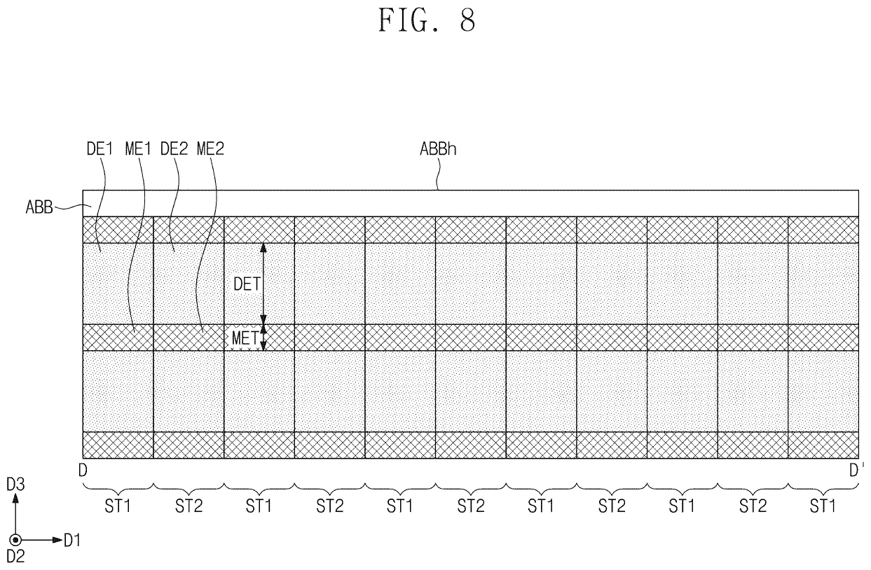

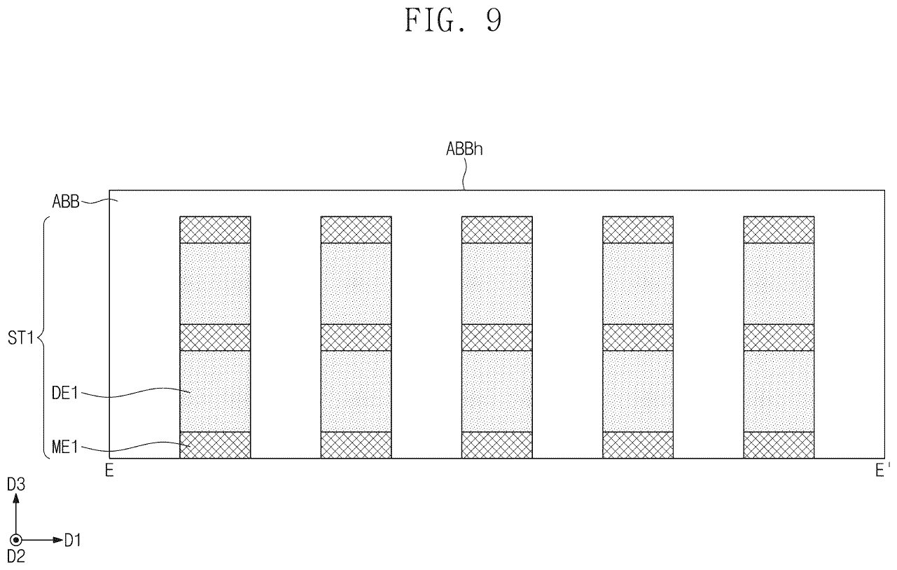

FIG. 7 is a plan view illustrating a first optical filter according to some example embodiments of the inventive concepts. FIG. 8 is a sectional view taken along a line D-D′ of FIG. 7. FIG. 9 is a sectional view taken along a line E-E′ of FIG. 7. An element previously described with reference to FIGS. 4 to 6 may be identified by the same reference number without repeating an overlapping description thereof.

Referring to FIGS. 7, 8, and 9, the first optical filter F1 may include the first stack structures ST1, second stack structures ST2, and the optical absorption layer ABB. The second stack structures ST2 may be extended in the second direction D2. In the first optical filter F1, each of the second stack structures ST2 may be disposed along a column. The second stack structures ST2 may be spaced apart from each other in the first direction D1.

The first and second stack structures ST1 and ST2 may be line-shaped structures, which are respectively extended in the first and second directions D1 and D2 to cross each other, and the line-shaped structures may have a lattice shape in the first optical filter F1. That is, when viewed in a plan view, the first and second stack structures ST1 and ST2 may have a web shape.

For example, a distance between the first stack structures ST1 in the second direction D2 and a distance between the second stack structures ST2 in the first direction D1 may range from 700 nm to 800 nm.

Each of the second stack structures ST2 may include a second metal pattern ME2 and a second dielectric pattern DE2. The second dielectric pattern DE2 may be disposed on the second metal pattern ME2. In some example embodiments, a plurality of second metal patterns ME2 and a plurality of second dielectric patterns DE2 may be provided and may be alternately stacked in the third direction D3. Here, the second metal pattern ME2 may be disposed as the uppermost pattern of the second stack structure ST2.

The thickness DET of the first dielectric pattern DE1 may be larger than the thickness MET of the first metal pattern ME1. In some example embodiments, the thickness DET of the first dielectric pattern DE1 may be 3 to 4 times the thickness MET of the first metal pattern ME1. The thickness DET of the second dielectric pattern DE2 may be larger than the thickness MET of the second metal pattern ME2. In some example embodiments, the thickness DET of the second dielectric pattern DE2 may be 3 to 4 times the thickness MET of the second metal pattern ME2. Due to the addition of the second stack structure ST2, the density of the stack structures in the first optical filter F1 may be increased to expedite the plasmonic effect, and this may make it possible to reduce the thickness of the metal pattern in the stack structure.

The second metal pattern ME2 may be formed of or include at least one of, for example, gold, silver, or copper. The second dielectric pattern DE2 may be formed of or include at least one of silicon oxide or silicon nitride. However, example embodiments are not limited thereto.

The optical absorption layer ABB may be provided in the first optical filter F1 to fill spaces between the first stack structures ST1 and between the second stack structures ST2. In some example embodiments, the optical absorption layer ABB may be provided to fill an empty space which is defined by the first and second stack structures ST1 and ST2 extended along the row and column, respectively.

A height of the first stack structures ST1 and a height of the second stack structures ST2 may be lower than a level of the top surface ABBh of the optical absorption layer ABB. In some example embodiments, the height of the first stack structures ST1 and the height of the second stack structure ST2 may be 80% to 90% of the height of the first optical filter F1.

According to some example embodiments of the inventive concepts, the image sensor may include the optical filter on the substrate. The optical filter may include stack structures, in which the metal patterns and the dielectric patterns are stacked, and the optical absorption layer covering them. Here, the optical absorption layer may be configured to absorb short-wavelength light, such as visible light. The plasmonic effect may occur due to the metal and dielectric patterns provided in the stack structures, and this may make it possible to absorb or reflect light, which has a wavelength different from that of infrared light. As a result, it may be possible to reduce and/or prevent the light, which has a wavelength different from that of infrared light, into the substrate, to increase the transmittance of infrared light, and/or to reduce an optical noise. In this case, the image sensor with improved sensitivity may be provided.

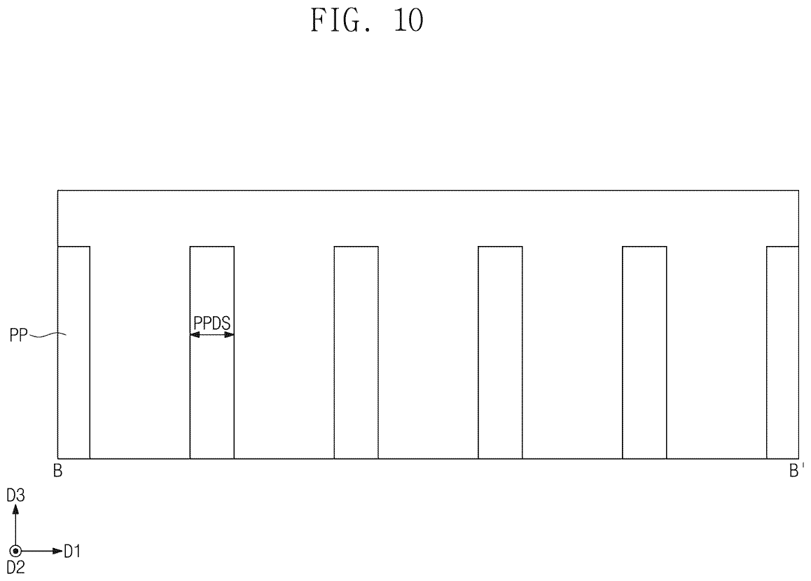

FIGS. 10, 11, and 12 are sectional views illustrating a process of fabricating a first optical filter, according to some example embodiments of the inventive concepts. In detail, FIGS. 10, 11, and 12 are sectional views illustrating a process of fabricating the first optical filter F1 shown in FIGS. 4 to 6.

Referring to FIGS. 2, 5, and 10, a plurality of sacrificial patterns PP may be formed in a space, in which the first optical filter F1 will be formed. The formation of the sacrificial patterns PP may include forming a sacrificial layer, forming mask patterns (not shown) on the sacrificial layer, patterning a sacrificial layer using the mask patterns as an etch mask, and removing the mask patterns. In some example embodiments, a length PPDS between the sacrificial patterns PP in the first direction D1 may range from 700 nm to 800 nm.

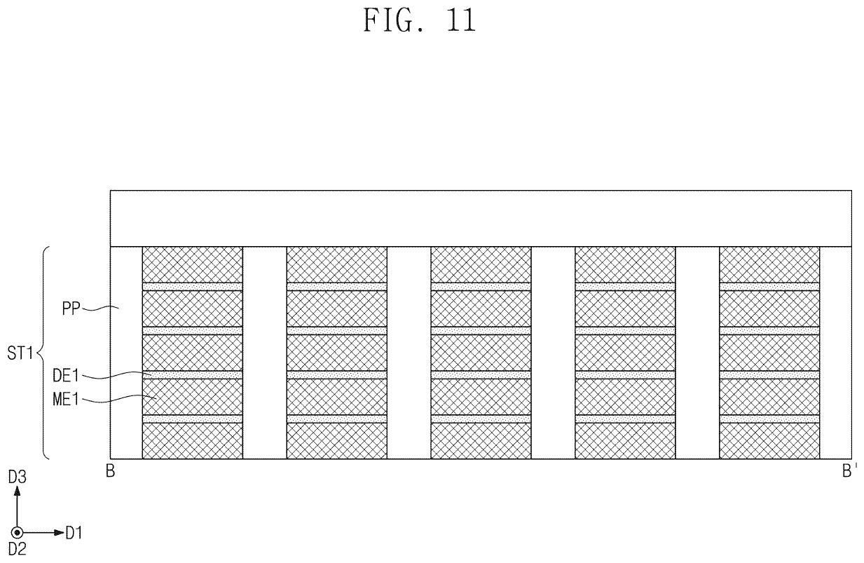

Referring to FIG. 11, the first stack structures ST1 may be formed between the sacrificial patterns PP, which are spaced apart from each other. The first stack structure ST1 may be formed by repeating steps of forming the first metal pattern ME1 and forming the first dielectric pattern DE1 on the first metal pattern ME1. That is, the first metal pattern ME1 and the first dielectric pattern DE1 may be alternately formed. Here, the first metal pattern ME1 may be formed as the uppermost pattern of the first stack structure ST1.

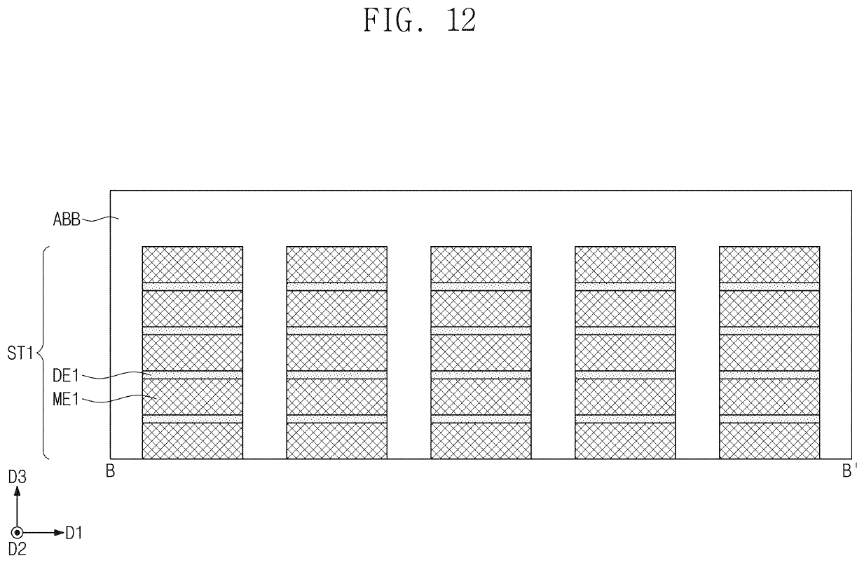

Referring to FIG. 12, the sacrificial patterns PP may be removed. Next, the optical absorption layer ABB may be formed on a region, from which the sacrificial patterns PP are removed. The optical absorption layer ABB may be formed in the first optical filter F1 to cover the first stack structures ST1. As a result of the formation of the optical absorption layer ABB, the first optical filter F1 may be formed.

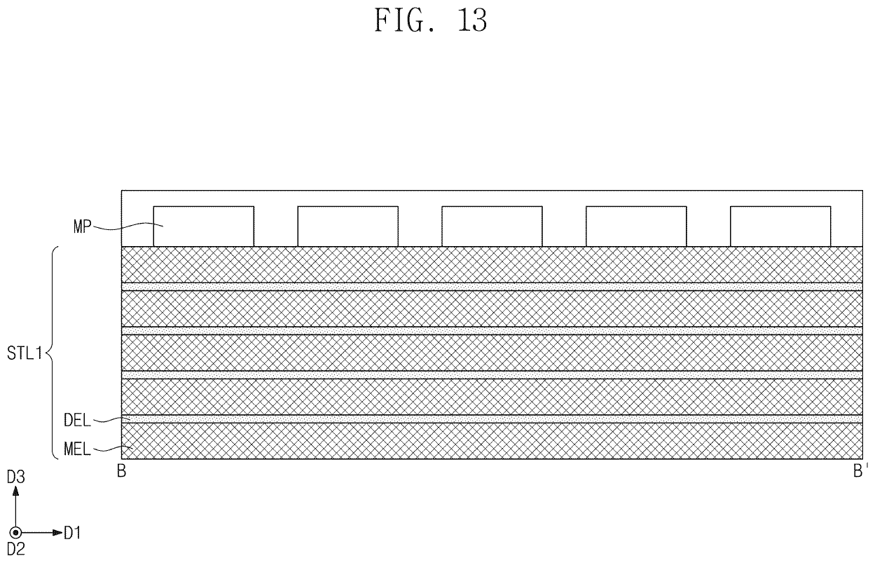

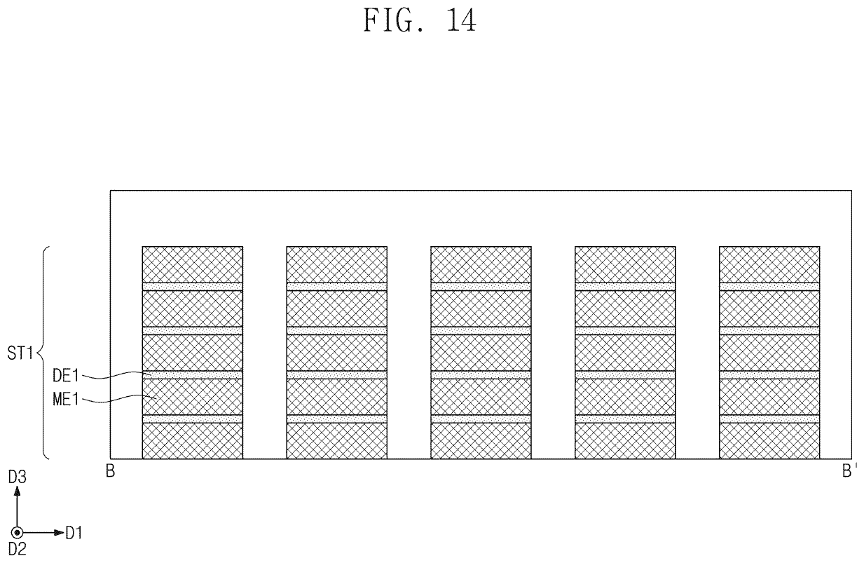

FIGS. 13 and 14 are sectional views illustrating a process of fabricating a first optical filter, according to some example embodiments of the inventive concepts. In detail, FIGS. 13 and 14 are sectional views illustrating a process of fabricating the first optical filter F1 shown in FIGS. 4 to 6.

Referring to FIGS. 2 and 13, a first stack layer STL1 may be formed in a space, in which the first optical filter F1 will be formed. The formation of the first stack layer STL1 may include repeatedly forming a first metal layer MEL1 and a first dielectric layer DEL1. Here, the first metal layer MEL1 may be formed as the uppermost layer of the first stack layer STL1.

A mask pattern MP may be disposed on the first stack layer STL1. The mask pattern MP may define regions, in which the first stack structures ST1 will be formed.

Referring to FIG. 14, a patterning process using the mask pattern MP as an etch mask may be performed on the first stack layer STL1. As a result of the patterning process, the first stack structures ST1 may be formed from the first stack layer STL1. Each of the first stack structures ST1 may include the first metal patterns ME1 and the first dielectric patterns DE1.

Next, the mask pattern MP may be removed, and then, since the optical absorption layer ABB is formed to cover the first stack structures ST1, the formation of the first optical filter F1 may be finished.

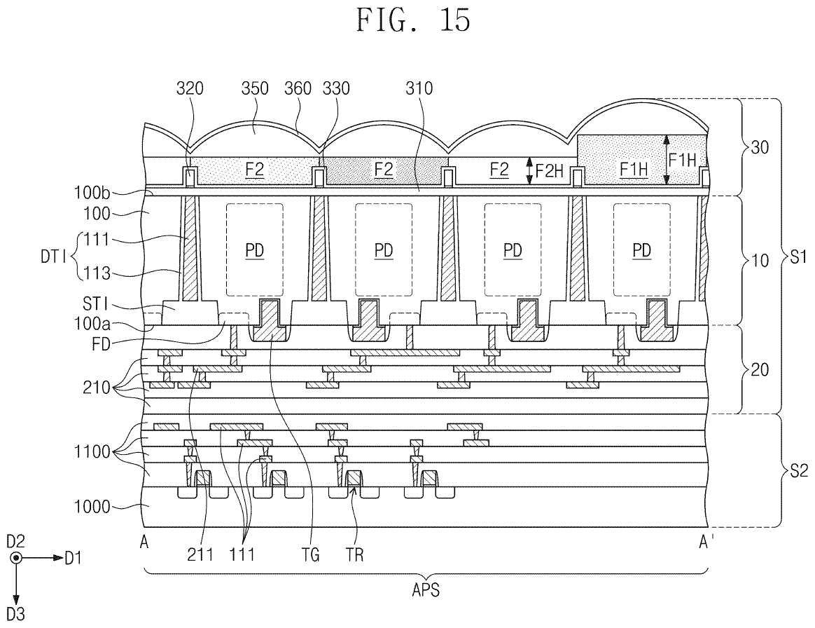

FIG. 15 is a sectional view illustrating an image sensor according to some example embodiments of the inventive concepts. For concise description, an element previously described with reference to FIG. 2 may be identified by the same reference number without repeating an overlapping description thereof.

Referring to FIG. 15, the first optical filter F1 of the image sensor may have a first height F1H. The second optical filter F2 may have a second height F2H. The first height F1H may be larger than the second height F2H. In some example embodiments, the first height F1H may be 1.5 to 2 times the second height F2H.

Thus, a level of a top surface of a micro lens 350 placed on the first optical filter F1 may be higher than a level of a top surface of the micro lens 350 placed on the second optical filter F2.

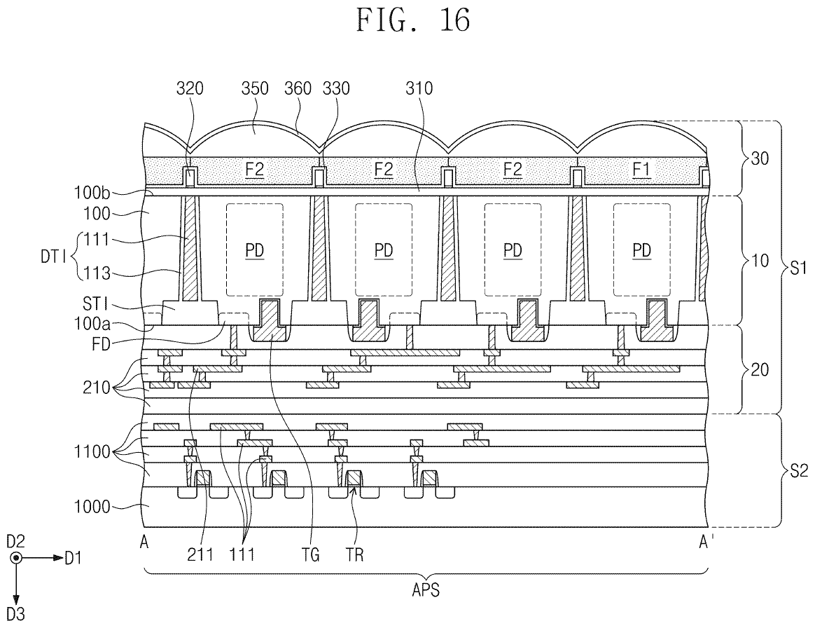

FIG. 16 is a sectional view illustrating an image sensor according to some example embodiments of the inventive concepts.

Referring to FIG. 16, the second optical filter F2 of the image sensor may have substantially the same or similar structure as the first optical filter F1 described with reference to FIGS. 4 to 6 and FIGS. 7 to 9. That is, the second optical filter F2 may include a plurality of stack structures and a second color filter, which is provided to fill a region between the stack structures and to cover the stack structures. The second color filter may be a blue color filter. Here, the second chip S2 may include circuits, which are configured to perform a global shutter operation.

According to some example embodiments of the inventive concepts, an image sensor may include an optical filter that is disposed on a substrate. The optical filter may include metal patterns and dielectric patterns which are repeatedly stacked. As a result, light, which has a wavelength different from that of the infrared light, may be absorbed or reflected, due to the plasmonic effect caused by the metal patterns and the dielectric patterns. Thus, the transmittance of infrared light incident into the substrate may be increased, the transmittance of visible light may be decreased, and/or the noise of the image sensor may be reduced.

While example embodiments of the inventive concepts have been particularly shown and described, it will be understood by one of ordinary skill in the art that variations in form and detail may be made therein without departing from the spirit and scope of the attached claims.

What is claimed is:

1. An image sensor, comprising:
a substrate including a plurality of photoelectric conversion parts; and
a first optical filter and a second optical filter on a top surface of the substrate and spaced apart from each other in a first direction,
wherein the first optical filter comprises
a stack structure and an optical absorption layer covering the stack structure,
the stack structure extending in the first direction,
the stack structure comprises a metal pattern and a dielectric pattern on the metal pattern, and
the second optical filter comprises at least one of a red color filter, a green color filter, and a blue color filter.

2. The image sensor of claim 1, wherein
the metal pattern comprises at least one of gold, silver, or copper,
the dielectric pattern comprises at least one of silicon oxide or silicon nitride, and
the optical absorption layer comprises at least one of copper phthalocyanine (CuPc) and cobalt aluminum oxide (CoAl₂O₄).

3. The image sensor of claim 1, wherein a height of the stack structure ranges from 60% to 80% of a level of a top surface of the optical absorption layer.

4. The image sensor of claim 1, wherein
the metal pattern is included in a plurality of metal patterns,
the dielectric pattern is included in a plurality of dielectric patterns, and
the stack structure comprises the plurality of metal patterns and the plurality of dielectric patterns alternately stacked, and
an uppermost metal pattern of the plurality of metal patterns is an uppermost pattern of the stack structure.

5. The image sensor of claim 1, wherein a thickness of the metal pattern is 5 to 10 times a thickness of the dielectric pattern.

6. The image sensor of claim 1, wherein
the stack structure has a lattice shape in a plan view defined by first and second line-shaped structures,
the first line-shaped structures extending in the first direction, and
the second line-shaped structures extending in a second direction, the second direction being parallel to the top surface of the substrate and perpendicular to the first direction.

7. The image sensor of claim 6, wherein a height of the stack structure ranges from 80% to 90% of a level of a top surface of the optical absorption layer.

8. The image sensor of claim 6, wherein a thickness of the dielectric pattern is 3 to 4 times a thickness of the metal pattern.

9. The image sensor of claim 6, wherein the optical absorption layer is configured to absorb visible light.

10. An image sensor, comprising:
a substrate including a plurality of photoelectric conversion parts; and
a first optical filter and a second optical filter on a top surface of the substrate and spaced apart from each other in a first direction, the first direction being parallel to the top surface of the substrate,
wherein the first optical filter comprises
a plurality of first stack structures spaced apart from each other in the first direction and arranged along a row direction, and
an optical absorption layer covering the first stack structures,
each of the first stack structures extends in a second direction, is the second direction being parallel to the top surface of the substrate and perpendicular to the first direction,
each of the first stack structures includes a first material pattern and a second material pattern alternately stacked,
the first material pattern and the second material pattern comprise different materials from each other, and
the second optical filter is at least one of a red color filter, a green color filter, and a blue color filter.

11. The image sensor of claim 10, wherein a distance of the first stack structures in the first direction ranges from 700 nm to 800 nm.

12. The image sensor of claim 10, wherein the optical absorption layer fills a space between the first stack structures.

13. The image sensor of claim 10, wherein
the first optical filter further comprises
a plurality of second stack structures spaced apart from each other in the second direction and are arranged along a column, and
each of the second stack structures extends in the first direction.

14. The image sensor of claim 13, wherein
the first material pattern comprises at least one of gold, silver, or copper, and
the second material pattern comprises at least one of silicon oxide or silicon nitride.

15. The image sensor of claim 13, wherein the first stack structures and the second stack structures have a lattice shape in a plan view.

16. An image sensor, comprising:
a substrate comprising a sensing region, an optical black region, and a pad region, and the substrate having a first surface and a second surface opposite to each other;
a plurality of photoelectric conversion parts in the sensing region of the substrate;
an isolation structure in the substrate separating the photoelectric conversion parts from each other; and
a first optical filter and a second optical filter on the first surface of the substrate,
wherein the first and second optical filters are spaced apart from each other in a first direction, the first direction being parallel to the first surface,
the first optical filter comprises a plurality of stack structures and a first color filter,
the second optical filter comprises a second color filter,
each of the stack structures comprises a plurality of metal patterns and a plurality of dielectric patterns,
the plurality of metal patterns and the plurality of dielectric patterns in the first optical filter are alternately stacked in a vertical direction,
the first color filter in the first optical filter fills a region between the stack structures and covers the stack structures,
the first color filter comprises a blue color filter, and
the second color filter comprises at least one of a blue color filter, a green color filter, and a red color filter.

17. The image sensor of claim 16, wherein
each of the plurality of metal patterns comprises at least one of gold, silver, or copper,
each of the plurality of dielectric patterns comprises at least one of silicon oxide or silicon nitride, and
the first color filter comprises at least one of copper phthalocyanine (CuPc) and cobalt aluminum oxide (CoAl₂O₄).

18. The image sensor of claim 16, wherein a height of the first optical filter is 1.5 to 2 times a height of the second color filter.

19. The image sensor of claim 16, wherein the first optical filter is surrounded by the second optical filter in a plan view.

20. The image sensor of claim 16, wherein
the second optical filter comprises a plurality of stack structures,
the second color filter is a blue color filter, and
the second color filter fills a region between the stack structures and covers the stack structures.
